(19) United States
(12) Patent Application Publication
(10) Pub. No.: US 2026/0255565 A1
(43) Pub. Date: Aug. 27, 2026

(54) ELECTROMAGNETIC INTERFERENCE SHIELDING FILM COMPRISING HETEROGENEOUSLY STACKED METAL-MXENE AND METHOD FOR PREPARING THE SAME

(71) Applicants: GWANGJU INSTITUTE OF SCIENCE AND TECHNOLOGY, Gwangju (KR); SEOUL NATIONAL UNIVERSITY R& DB FOUNDATION, Seoul (KR)

(72) Inventors: Young Chang JOO, Seoul (KR); Han Wool YEON, Gwangju (KR); Geo San KANG, Seoul (KR)

(21) Appl. No.: 19/449,341

(22) Filed: Jan. 14, 2026

(30) Foreign Application Priority Data
Feb. 26, 2025 (KR) 10-2025-0025195

(51) Int. Cl. H05K 9/00; C23C 14/02; C23C 14/18; C23C 14/30; C23C 24/08; C23C 28/00; H10W 42/20

(52) U.S. Cl. CPC H05K 9/0088; C23C 14/024; C23C 14/18; C23C 14/30; C23C 24/085; C23C 28/34; H10W 42/281

(57) ABSTRACT

The present inventive concept relates to an electromagnetic interference shielding film comprising a heterogeneously stacked metal-MXene (MX), and a method for preparing the same. With a sandwich structure in which an MXene layer is disposed between metal thin film layers, the electromagnetic interference shielding film exhibits excellent electromagnetic wave shielding efficiency even at a reduced thickness compared to conventional films.

### CROSS-REFERENCE TO RELATED PATENT APPLICATION

This application claims the benefit of Korean Patent Application No. 10-2025-0025195, filed on Feb. 26, 2025, in the Korean Intellectual Property Office, the disclosure of which is incorporated herein in its entirety by reference.

### BACKGROUND OF THE INVENTIVE CONCEPT

### 1. Field of the Inventive Concept

The present inventive concept relates to an electromagnetic interference shielding film comprising a heterogeneously stacked metal-MXene (MX), and a method for preparing the same. More specifically, the present inventive concept relates to an embedded MXene-in-metal (EXIM) electromagnetic interference shielding film in which an MXene is stacked between metals in a sandwich structure, thereby exhibiting excellent shielding performance at a reduced thickness.

### 2. Description of the Related Art

With the development of smart electronic devices, the portability and wearability of electronic devices have become important, and therefore the physical thickness of IC chips, such as thinned wafers and wafer-free integrated circuit (IC) chips, has been significantly reduced. Accordingly, extensive research has been conducted to reduce the thickness of packaging materials, thereby decreasing the overall thickness of electronic devices. For example, various experiments are being conducted to reduce the thickness of electromagnetic interference (EMI) shielding films capable of protecting IC chips from electromagnetic pollution.

However, conventional electromagnetic interference shielding films have a thick metal cage structure surrounding an IC chip, and the shielding performance deteriorates as the thickness of the metal cage is reduced. Therefore, in order to improve the performance of electromagnetic interference shielding films, pores have been formed in metals and two-dimensional conductive shielding materials, such as titanium carbide and titanium nitride, to induce the absorption of electromagnetic waves through absorption during multiple internal reflections (AMIR), thereby improving shielding efficiency. However, there is a limitation in reducing the thickness of the shielding films including such pores, and the shielding films suffer from low spatial uniformity and high bending rigidity. Furthermore, the shielding films including pores require high processing temperatures and are incompatible with conventional packaging technologies that directly deposit them onto the surface of an IC chip, and therefore, there have been no successful cases of forming a shielding film including pores on an IC chip.

Therefore, there is a need to develop an electromagnetic interference shielding film that has excellent AMIR performance, has a reduced thickness, and can actually be deposited.

### SUMMARY OF THE INVENTIVE CONCEPT

The present inventive concept has been made in an effort to solve the above-described problems associated with the prior art, and a first object of the present inventive concept is to provide an electromagnetic interference shielding film comprising a heterogeneously stacked metal-MXene (MX).

A second object of the present inventive concept is to provide a method for preparing an electromagnetic interference shielding film comprising a heterogeneously stacked metal-MXene (MX) in order to achieve the first object.

In order to achieve the above-described first object, the present inventive concept provides an electromagnetic interference shielding film comprising a heterogeneously stacked metal-MXene. The electromagnetic interference shielding film comprising a heterogeneously stacked metal-MXene has a sandwich structure including a lower metal thin film, an MXene layer positioned on the metal thin film, and an upper metal thin film for electromagnetic shielding positioned on the MXene layer and made of the same material as the lower metal thin film. The lower metal thin film and the upper metal thin film are configured to induce AMIR by dipoles on the surface of the MXene layer at the interfaces in contact with the MXene layer, thereby improving electromagnetic shielding performance.

In order to achieve the above-described second object, the present inventive concept provides a method for preparing an electromagnetic interference shielding film comprising a heterogeneously stacked metal-MXene, the method comprising: forming a sacrificial layer on a substrate; depositing a lower metal thin film on the sacrificial layer; coating an interfacial adhesion promoter on the lower metal thin film; coating an MXene layer on the lower metal thin film coated with the interfacial adhesion promoter; coating an interfacial adhesion promoter on the MXene layer; and depositing an upper metal thin film on the MXene layer coated with the interfacial adhesion promoter. A multilayered electromagnetic interference shielding film may be prepared by additionally stacking the MXene layer and the metal thin film on the upper metal thin film in this order.

According to the present inventive concept as described above, the electromagnetic interference shielding film comprising a heterogeneously stacked metal-MXene can be prepared to have a reduced thickness compared to conventional electromagnetic interference shielding films including pores, since the non-porous MXene layer is inserted into the metal thin film layers and is therefore not restricted by the minimum thickness required for forming pores, and the resulting film exhibits excellent uniformity and processing compatibility. Therefore, the electromagnetic interference shielding film comprising a heterogeneously stacked metal-MXene has low bending rigidity due to its reduced thickness and thus can be easily formed on the surfaces of various IC chips. Moreover, since it does not require a step of additionally forming a pore structure within the electromagnetic interference shielding film comprising a heterogeneously stacked metal-MXene, it exhibits excellent spatial uniformity and reproducibility, and therefore the passivation yield does not decrease, resulting in excellent shielding performance.

The electromagnetic interference shielding film comprising a heterogeneously stacked metal-MXene forms an electromagnetic wave confinement barrier due to a high reflection loss at the interface where the metal thin film layer and the MXene layer are joined, which results from the conductivity mismatch between the metal thin film layer and the MXene layer. Furthermore, the interface and the dipoles of MXene flakes absorb reflected waves and thereby generate effective absorption during multiple internal reflections (AMIR) within the electromagnetic interference shielding film, thus achieving excellent electromagnetic shielding efficiency.

The electromagnetic interference shielding film comprising a heterogeneously stacked metal-MXene may have a multilayer stacked structure in which a metal thin film layer and an MXene layer are sequentially stacked, and can exhibit excellent shielding performance as the number of junctions between the metal thin film layers and the MXene layers increases.

### BRIEF DESCRIPTION OF THE DRAWINGS

The above and other features and advantages of the present inventive concept will become more apparent by describing in detail exemplary embodiments thereof with reference to the attached drawings in which:

FIGS. 1A and 1B show schematic views of electromagnetic interference shielding films comprising a heterogeneously stacked metal-MXene according to preferred embodiments of the present inventive concept;

FIG. 2 is a graph illustrating the shielding effectiveness (SE) according to a preferred embodiment of the present inventive concept;

FIG. 3 shows a benchmarking graph illustrating the average SE according to the thickness of electromagnetic interference shielding films according to preferred embodiments of the present inventive concept;

FIGS. 4A through 4G show scanning electron microscopy (SEM), transmission electron microscopy (TEM), and energy dispersive X-ray spectroscopy (EDS) mapping images of an electromagnetic interference shielding film according to a preferred embodiment of the present inventive concept;

FIGS. 5A and 5B show a bending test image and a curvature measurement graph according to a preferred embodiment of the present inventive concept;

FIGS. 6A through 6F show graphs illustrating the average SE according to the thickness of electromagnetic interference shielding films according to preferred embodiments of the present inventive concept, together with the slope values of the graphs and the associated electrical conductivity;

FIG. 7A through FIG. 7J show graphs illustrating the measured SE values according to preferred embodiments of the present inventive concept, as well as the stacking effect on the average SE value;

FIGS. 8A and 8B and FIGS. 9A through 9C show graphs illustrating the results of repeated SE measurements according to preferred embodiments of the present inventive concept;

FIGS. 10A through 10E show graphs illustrating the AMIR mechanism according to preferred embodiments of the present inventive concept;

FIGS. 11A through 11G show graphs illustrating the SE curves of electromagnetic interference shielding films according to preferred embodiments of the present inventive concept;

FIG. 12 shows graphs illustrating the synergistic SE and the average SE according to the thickness of electromagnetic interference shielding films according to preferred embodiments of the present inventive concept;

FIGS. 13A and 13B show graphs illustrating the measured synergistic SE according to preferred embodiments of the present inventive concept, depending on the presence or absence of a metal thin film and an MXene well structure;

FIGS. 14A through 14F show graphs illustrating the SE measurement results according to the multilayer structure of electromagnetic interference shielding films according to preferred embodiments of the present inventive concept;

FIG. 15 shows graphs illustrating the measured average SE and electrical resistance values of electromagnetic interference shielding films according to preferred embodiments of the present inventive concept, depending on the presence or absence of a passivation layer on the shielding films;

FIGS. 16A through 16H show images illustrating the changes in the surface morphology of electromagnetic interference shielding films according to preferred embodiments of the present inventive concept, depending on the presence or absence of a passivation layer;

FIGS. 17A through 17D show graphs illustrating the average SE curves of electromagnetic interference shielding films according to preferred embodiments of the present inventive concept, depending on the presence or absence of a passivation layer;

FIGS. 18A through 18C show graphs illustrating the malfunction of a Bluetooth speaker caused by electromagnetic noise according to a preferred embodiment of the present inventive concept; and

FIG. 19 is a graph illustrating the effect of shielding on the integrity of Bluetooth signal according to a preferred embodiment of the present inventive concept.

### DETAILED DESCRIPTION OF THE INVENTIVE CONCEPT

As the present inventive concept allows for various changes and numerous embodiments, particular embodiments will be illustrated in the drawings and described in detail in the written description. However, this is not intended to limit the present inventive concept to particular modes of practice, and it is to be appreciated that all changes, equivalents, and substitutes that do not depart from the spirit and technical scope of the present inventive concept are encompassed in the present inventive concept.

Unless defined otherwise, all terms used herein including technical or scientific terms have the same meaning as those generally understood by those skilled in the art to which the present inventive concept pertains. It will be further understood that terms defined in dictionaries that are commonly used should be interpreted as having meanings that are consistent with their meanings in the context of the relevant art and should not be interpreted as having ideal or excessively formal meanings unless clearly defined in the present application.

As used herein, the term “MXene” refers to a new type of two-dimensional material that mainly belongs to metal carbides, nitrides, or carbonitrides, and may be used interchangeably with the term “MXene”. These terms have the same meaning throughout the present description.

As used herein, the term “electromagnetic interference shielding film comprising a heterogeneously stacked metal-MXene” refers to an electromagnetic interference shielding film in which an MXene layer is stacked in a sandwich structure between metal thin films, and may be used interchangeably with the term “embedded MXene-in-metal (EXIM) electromagnetic interference shielding film” to distinguish it from electromagnetic interference shielding films that employ different structures or different materials. These terms have the same meaning throughout the present description.

Hereinafter, various embodiments of the present inventive concept will be described in more detail with reference to the accompanying drawings.

### EXAMPLES

In an aspect, the present inventive concept provides an electromagnetic interference shielding film comprising a heterogeneously stacked metal-MXene.

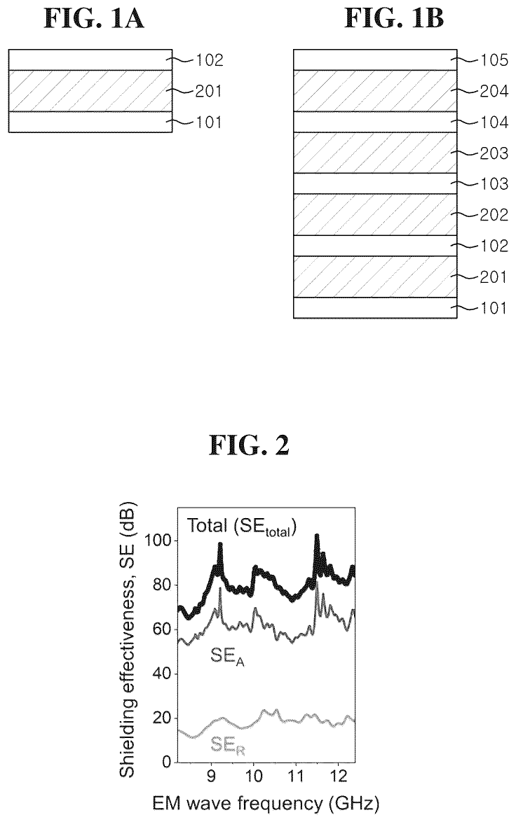

FIGS. 1A and 1B show schematic views of electromagnetic interference shielding films comprising a heterogeneously stacked metal-MXene according to the present inventive concept.

Referring to FIGS. 1A and 1B, the electromagnetic interference shielding film comprising a heterogeneously stacked metal-MXene has a sandwich structure including a lower metal thin film 101, an MXene layer 201 deposited on the lower metal thin film 101, and an upper metal thin film 102 deposited on the MXene layer 201, as shown in FIG. 1A. Referring to FIG. 1B, the electromagnetic interference shielding film comprising a heterogeneously stacked metal-MXene may form a multilayer sandwich structure including two or more MXene layers formed by repeatedly stacking metal thin films 101, 102, 103, 104, and 105 and MXene layers 201, 202, 203, and 204.

When a multilayer sandwich structure including two or more metal thin films and MXene layers is formed, the increased number of junctions between the metal thin film layers and the MXene layers allows the electric dipoles of the terminal groups on the surfaces of the MXene layers to interact with electromagnetic waves through dipole polarization, thereby attenuating the electromagnetic waves through a relaxation mechanism. Therefore, the electromagnetic shielding efficiency can be improved as the number of junctions between the metal thin film layers and the MXene layers increases due to the multilayer stacking.

The MXene layer may preferably be formed as thin as possible with a minimum thickness that can ensure uniform film quality. Since the dipoles present at the metal-MXene interface play a critical role in the AMIR effect resulting from the sandwich structure, if the MXene layer can be formed uniformly, high shielding performance can be maintained even when the thickness of the thin film is reduced from 1 μm to 0.2 μm. As the thickness decreases, the bending strength is reduced, allowing the thin film to adhere effectively to the surface of an IC chip.

The electromagnetic interference shielding film comprising a heterogeneously stacked metal-MXene may preferably have a thickness of 2 μm or less. If the thickness of the electromagnetic interference shielding film comprising a heterogeneously stacked metal-MXene exceeds 2 μm, it may be difficult to attach the electromagnetic interference shielding film of the present inventive concept onto an IC chip for electromagnetic shielding due to a limitation in bending.

The electromagnetic interference shielding film comprising a heterogeneously stacked metal-MXene may have an electromagnetic shielding effectiveness (SE) of 69.2 (±1.6) dB or higher.

The electromagnetic interference shielding film comprising a heterogeneously stacked metal-MXene of the present inventive concept may include a passivation layer formed on an upper portion thereof to prevent oxidation. The passivation layer formed on the electromagnetic interference shielding film comprising a heterogeneously stacked metal-MXene may prevent damage to the electromagnetic interference shielding film caused by oxidation, such as humidity or discoloration, thereby preventing a reduction in shielding performance.

The metal thin film may be any one selected from the group consisting of metal materials including Cu, Au, and Ag, but is not limited thereto, and any metal capable of blocking, absorbing, or reflecting electromagnetic waves is sufficient.

In another aspect, the present inventive concept provides a method for preparing an electromagnetic interference shielding film comprising a heterogeneously stacked metal-MXene.

The electromagnetic interference shielding film comprising a heterogeneously stacked metal-MXene may be prepared by a method comprising: a first step of forming a sacrificial layer on a substrate, a second step of depositing a lower metal thin film on the sacrificial layer formed in the first step, a third step of coating an interfacial adhesion promoter on the lower metal thin film deposited in the second step, a fourth step of coating an MXene layer on the lower metal thin film coated with the interfacial adhesion promoter in the third step, a fifth step of coating an interfacial adhesion promoter on the MXene layer coated in the fourth step, and a sixth step of depositing an upper metal thin film on the MXene layer coated with the interfacial adhesion promoter in the fifth step.

In the first step, a sacrificial layer may be formed on a substrate.

In the second step, a lower metal thin film may be formed on the sacrificial layer.

The lower metal thin film may be any one selected from the group consisting of metal materials including Cu, Au, and Ag, but is not limited thereto, and any metal capable of blocking, absorbing, or reflecting electromagnetic waves is sufficient.

In the third step, an interfacial adhesion promoter may be coated on the lower metal thin film to bond the MXene layer.

The interfacial adhesion promoter may be APTES or TiOx, but is not limited thereto, and any material capable of facilitating the bonding of the interface between the metal thin film and the MXene layer is sufficient.

In the fifth step, an MXene layer may be deposited.

The MXene layer may preferably be formed as thin as possible with a minimum thickness that can ensure uniform film quality. Since the dipoles present at the metal-MXene interface play a critical role in the AMIR effect resulting from the sandwich structure, if the MXene layer can be formed uniformly, high shielding performance can be maintained even when the thickness of the thin film is reduced from 1 μm to 0.2 μm. As the thickness decreases, the bending strength is reduced, allowing the thin film to adhere effectively to the surface of an IC chip.

In the fifth step, an interfacial adhesion promoter may be coated on the MXene layer.

The interfacial adhesion promoter may be APTES or TiOx, but is not limited thereto, and any material capable of facilitating the bonding of the interface between the metal thin film and the MXene layer is sufficient.

In the sixth step, an upper metal thin film may be deposited to prepare an electromagnetic interference shielding film comprising a heterogeneously stacked metal-MXene.

The upper metal thin film may be any one selected from the group consisting of metal materials including Cu, Au, and Ag, but is not limited thereto, and any metal capable of blocking, absorbing, or reflecting electromagnetic waves is sufficient.

The electromagnetic interference shielding film comprising a heterogeneously stacked metal-MXene may be a multilayered electromagnetic interference shielding film including two or more MXene layers formed by repeating the third to sixth steps.

The electromagnetic interference shielding film comprising a heterogeneously stacked metal-MXene may preferably have a thickness of 2 μm or less. If the thickness of the electromagnetic interference shielding film comprising a heterogeneously stacked metal-MXene exceeds 2 μm, it may be difficult to attach the electromagnetic interference shielding film of the present inventive concept onto an IC chip for electromagnetic shielding due to a limitation in bending.

The electromagnetic interference shielding film comprising a heterogeneously stacked metal-MXene may have an electromagnetic shielding effectiveness (SE) of 69.2 (±1.6) dB or higher.

The electromagnetic interference shielding film comprising a heterogeneously stacked metal-MXene of the present inventive concept may include a passivation layer formed on an upper portion thereof to prevent oxidation. The passivation layer formed on the electromagnetic interference shielding film comprising a heterogeneously stacked metal-MXene may prevent damage to the electromagnetic interference shielding film caused by oxidation, such as humidity or discoloration, thereby preventing a reduction in shielding performance.

### Preparation Example 1-1: Mxene (mx)/cu Structure

Ti₃C₂Tₓ MXene was synthesized by selectively etching Al in Ti₃AlC₂. After dispersing Ti₃C₂Tₓ MXene flakes in distilled water to prepare an MXene mixture having a concentration of 2 mg/mL, the mixture was subjected to ultrasonication to prepare an MXene colloidal solution. A PMMA thin film was formed as a sacrificial layer on a silicon substrate, and the MXene colloidal solution was spray-coated on the PMMA thin film and then heated at 40° C. to form an MXene layer. After applying APTES onto the MXene layer, Cu was thinly deposited using an electron beam evaporator under high vacuum conditions to form a metal thin film, and the sacrificial layer was then removed to prepare an electromagnetic interference shielding film having an MX/Cu structure.

### Preparation Example 1-2: Cu/mx Structure

Except for changing the deposition order of Cu and MX, an electromagnetic interference shielding film having a Cu/MX structure was prepared under the same conditions as in Preparation Example 1 -1

### Preparation Example 1-3: Cu/mx (0.4 μm)/cu Structure

Except for coating the MXene layer to a thickness of 0.4 μm, applying APTES onto the MXene layer, and forming an upper metal thin film by thinly depositing Cu using an electron beam evaporator under high vacuum conditions, an electromagnetic interference shielding film having a Cu/MX (0.4 μm)/Cu structure was prepared under the same conditions as in Preparation Example 1-2.

### Preparation Example 1-4: Cu/mx (0.2 μm)/cu Structure

Except for coating the MXene layer to a thickness of 0.2 μm, an electromagnetic interference shielding film having a Cu/MX (0.2 μm)/Cu structure was prepared under the same conditions as in Preparation Example 1-3.

### Preparation Example 1-5: Cu/mx (1 μm)/cu Structure

Except for coating the MXene layer to a thickness of 1 μm, an electromagnetic interference shielding film having a Cu/MX (1 μm)/Cu structure was prepared under the same conditions as in Preparation Example 1-3.

### Preparation Example 1-6: Structure Including Two Mx Layers

Except for forming a multilayer structure by repeating the deposition of an MXene layer and a metal thin film on the upper metal thin film one additional time, an electromagnetic interference shielding film having a structure including two MXene layers was prepared under the same manner as in Preparation Example 1-4.

### Preparation Example 1-7: Structure Including Three MX Layers

Except for forming a multilayer structure by repeating the deposition of an MXene layer and a metal thin film on the upper metal thin film two additional times in the same manner as in Preparation Example 1-4, an electromagnetic interference shielding film having a structure including three MXene layers was prepared under the same conditions.

### Preparation Example 1-8: Structure Including Four Mx Layers

Except for forming a multilayer structure by repeating the deposition of an MXene layer and a metal thin film on the upper metal thin film three additional times in the same manner as in Preparation Example 1-4, an electromagnetic interference shielding film having a structure including four MXene layers was prepared under the same conditions.

### Preparation Example 1-9: Structure Including Six MX Layers

Except for Forming a Multilayer Structure by Repeating the Deposition of an Mxene layer and a metal thin film on the upper metal thin film five additional times in the same manner as in Preparation Example 1-4, an electromagnetic interference shielding film having a structure including six MXene layers was prepared under the same conditions.

### Preparation Example 1-10: Structure Including a Passivation Layer

Except for forming a Cr—Al thin film as a passivation layer on the uppermost metal thin film, an electromagnetic interference shielding film having a structure including a passivation layer was prepared under the same conditions as in Preparation Example 1-7.

### Preparation Example 2: Ag/mx/ag Structure

Except for using Ag instead of Cu as the upper metal thin film, an electromagnetic interference shielding film having an Ag/MX/Ag structure was prepared under the same conditions as in Preparation Example 1-4.

### Preparation Example 3: TiOx/mx/TiOx Structure

Except for using TiOx instead of Cu as the upper metal thin film, an electromagnetic interference shielding film having a TiOx/MX/TiOx structure was prepared under the same conditions as in Preparation Example 1-4.

### Preparation Example 4: Au/mx/au Structure

Except for using Au instead of Cu as the upper metal thin film, an electromagnetic interference shielding film having an Au/MX/Au structure was prepared under the same conditions as in Preparation Example 1-4.

### Comparative Example 1-1

A single-metal electromagnetic interference shielding film having a Cu thickness of 0.1 μm was prepared.

### Comparative Example 1-2

A single-metal electromagnetic interference shielding film having a Cu thickness of 0.2 μm was prepared.

### Comparative Example 1-3

A single-metal electromagnetic interference shielding film having a Cu thickness of 0.4μm was prepared.

### Comparative Example 1-4

A single-metal electromagnetic interference shielding film having a Cu thickness of 0.6 μm was prepared.

### Comparative Example 2-1

After metallizing a silicon substrate with an Al thin film having a thickness of 100 nm, the MXene colloidal solution prepared in Preparation Example 1-1 was spray-coated onto the Al thin film to form an MXene layer having a thickness of 0.2 μm, and a single MXene electromagnetic interference shielding film separated from the substrate was prepared through selective electrochemical etching of the Al thin film.

### Comparative Example 2-2

Except for coating the MXene layer to a thickness of 0.4 μm, a single MXene electromagnetic interference shielding film was prepared under the same conditions as in Comparative Example 2-1.

### Comparative Example 2-3

Except for coating the MXene layer to a thickness of 0.6 μm, a single MXene electromagnetic interference shielding film was prepared under the same conditions as in Comparative Example 2-1.

### Comparative Example 2-4

Except for coating the MXene layer to a thickness of 1 μm, a single MXene electromagnetic interference shielding film was prepared under the same conditions as in Comparative Example 2-1.

### Comparative Example 3-1

A single-metal electromagnetic interference shielding film having a TiOx thickness of 0.1 μm was prepared.

### Comparative Example 3-2

A single-metal electromagnetic interference shielding film having a TiOx thickness of 0.2 μm was prepared.

### Comparative Example 3 -3

A single-metal electromagnetic interference shielding film having a TiOx thickness of 0.3 μm was prepared.

### Comparative Example 4-1

A single-metal electromagnetic interference shielding film having an Au thickness of 0.1 μm was prepared.

### Comparative Example 4-2

A single-metal electromagnetic interference shielding film having an Au thickness of 0.2 μm was prepared.

### Comparative Example 4-3

A single-metal electromagnetic interference shielding film having an Au thickness of 0.3 μm was prepared.

### Comparative Example 5-1

A single-metal electromagnetic interference shielding film having an Ag thickness of 0.1 μm was prepared.

### Comparative Example 5-2

A single-metal electromagnetic interference shielding film having an Ag thickness of 0.2 μm was prepared.

### Comparative Example 5-3

A single-metal electromagnetic interference shielding film having an Ag thickness of 0.3 μm was prepared.

### Comparative Example 6

Except for forming an Al₂O₃ layer instead of the MXene layer, an electromagnetic interference shielding film was prepared under the same conditions as in Preparation Example 1-4.

### Comparative Example 7

Except for forming a TiOx layer instead of the MXene layer, an electromagnetic interference shielding film was prepared under the same conditions as in Preparation Example 1-4.

### Comparative Example 8

Except for forming an AU layer instead of the MXene layer, an electromagnetic interference shielding film was prepared under the same conditions as in Preparation Example 1-4.

### Measurement Example 1

FIG. 2 is a graph illustrating the shielding effectiveness (SE) of the electromagnetic interference shielding film comprising a heterogeneously stacked metal-MXene prepared in Preparation Example 1-9, which includes twelve junctions between the metal thin films and the MXene layers.

Referring to FIG. 2, it was confirmed that the electromagnetic interference shielding film having a thickness of 1.9 μm prepared in Preparation Example 1-9 had an SEₜₒₜₐₗ of 69.2 (±1.6 ) dB or higher in the X-band range of 8.2 GHz to 12.4 GHz.

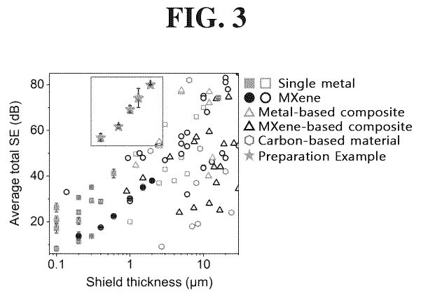

FIG. 3 is a graph illustrating the average SE values for comparing the performance of the electromagnetic interference shielding films comprising a heterogeneously stacked metal-MXene according to the present inventive concept.

Referring to FIG. 3, it was confirmed that the electromagnetic interference shielding films which have a sandwich structure in which the metal thin films and the MXene layers are repeatedly stacked, prepared in Preparation Examples 1-3 to 1-9 of the present inventive concept, exhibit excellent average SE values while maintaining a reduced thickness, compared to electromagnetic interference shielding films comprising a single metal, prepared in Comparative Examples 1-1 to 5-3, or other composite materials reported in the literature. In FIG. 3, it was confirmed that the electromagnetic interference shielding films having a shielding thickness of less than 2 μm exhibited average SE values of less than 60 dB, whereas the electromagnetic interference shielding films prepared in the Preparation Examples of the present inventive concept exhibited excellent average SE values of 60 dB to 80 dB even when the electromagnetic interference shielding films were prepared to have a thickness of less than 2 μm.

Therefore, it can be seen from FIGS. 2 and 3 that the electromagnetic interference shielding films comprising a heterogeneously stacked metal-MXene exhibit excellent shielding performance even at a thickness of 2 μm or less, and that when the thickness is 0.1 μm to 2 μm, the shielding films have an SEₜₒₜₐₗ value of 69.2 (±1.6 ) dB or higher, indicating that excellent shielding performance is maintained even with a reduced thickness.

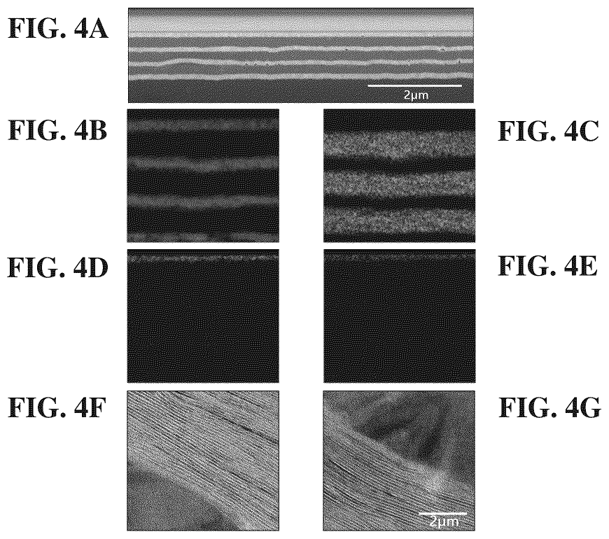

FIGS. 4A through 4G show scanning electron microscopy (SEM), transmission electron microscopy (TEM), and energy dispersive X-ray spectroscopy (EDS) mapping images of the electromagnetic interference shielding film prepared in Preparation Example 1-10. FIG. 4B is a Cu mapping image, FIG. 4C is a Ti mapping image, FIG. 4D is a Cr mapping image, and FIG. 4E is an Al mapping image. FIG. 4F is a TEM image of the interface between the lower copper thin film and the MXene layer, and FIG. 4G is a TEM image of the interface between the upper copper thin film and the MXene layer.

Referring to FIGS. 4A through 4G, it can be confirmed that the electromagnetic interference shielding film prepared in Preparation Example 1-10 has a sandwich structure in which four Cu thin films each having a thickness of 0.1 μm and three MXene layers each having a thickness of 0.2 μm are alternately stacked, and that the layers are uniformly stacked as shown in the elemental mapping images. Since the Cu thin films and the MXene layers do not mix and form uniform layers, the electromagnetic shielding performance can be improved due to interfacial reactions at the junctions. Furthermore, referring to the TEM images, no pores are formed inside the electromagnetic interference shielding film, and the interfaces at the junctions between the copper thin films and the MXene layers exhibit almost no pores due to the interfacial adhesion promoter. Therefore, non-uniformity of AMIR caused by the size or location of the pores can be prevented.

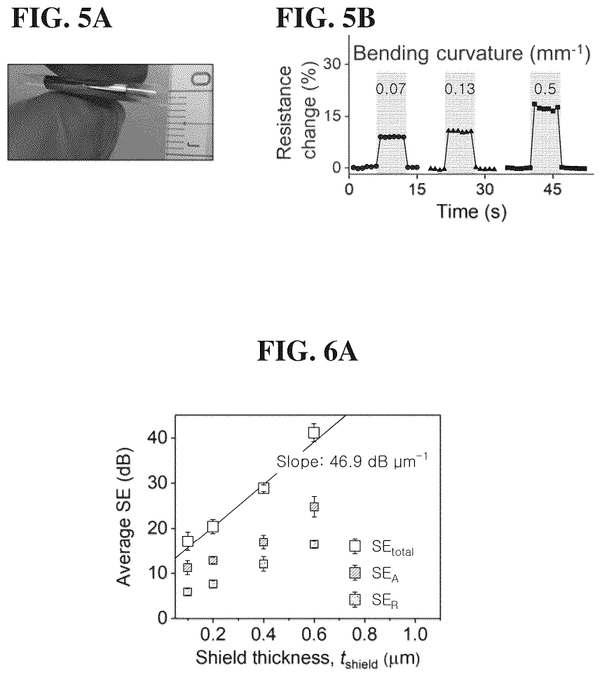

FIGS. 5A and 5B show a bending test image and a curvature measurement graph of the electromagnetic interference shielding film prepared in Preparation Example 1-10.

Referring to FIGS. 5A and 5B, it can be visually seen from FIG. 5A that the electromagnetic interference shielding film comprising a heterogeneously stacked metal-MXene is bent to a curvature of 0.5 mm. In addition, the curvature results shown in FIG. 5B demonstrate that reversible recovery is possible. Since the electromagnetic interference shielding film prepared in Preparation Example 1-10 has low bending rigidity and thus requires a supporting substrate, it can be inferred that conformal passivation of IC chips is possible.

### Measurement Example 2

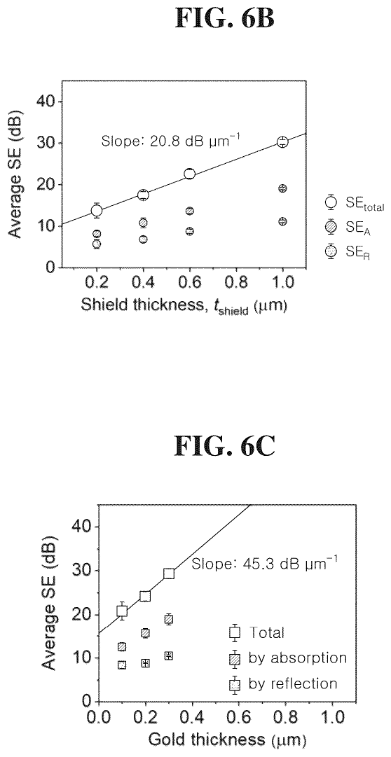

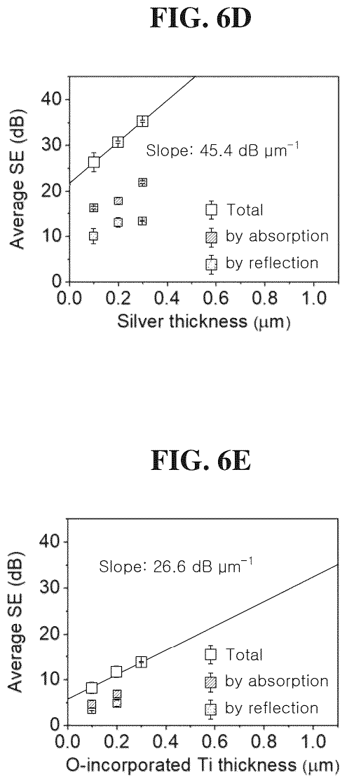

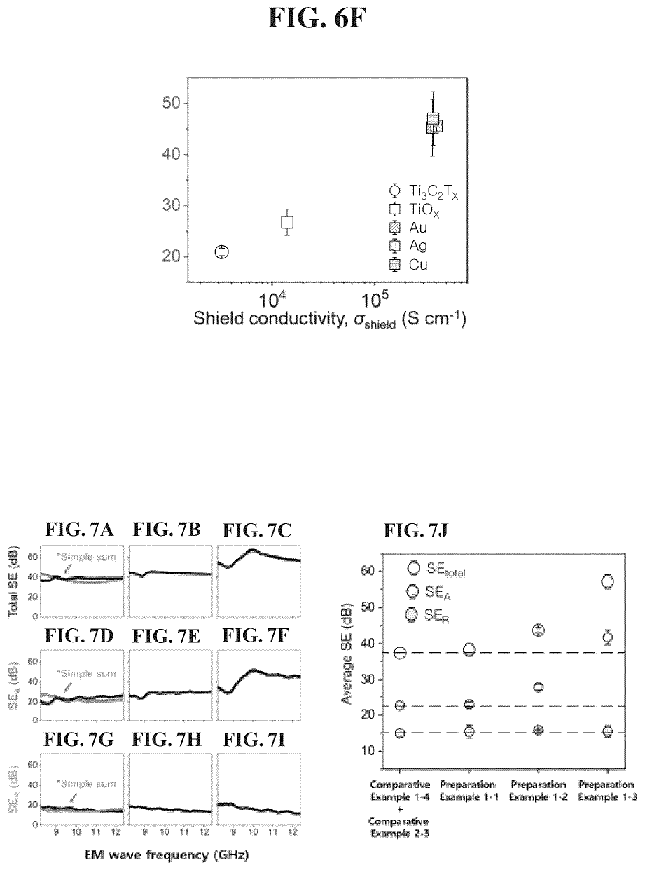

FIGS. 6A through 6F show graphs illustrating the average SE according to the thickness of the electromagnetic interference shielding films prepared in Comparative Examples 1-1 to 5-3, as well as graphs related to the electrical conductivity calculated therefrom. FIG. 6A shows measurements of single Cu thin films of Comparative Examples 1-1 to 1-4, FIG. 6B shows measurements of single Mx thin films of Comparative Examples 2-1 to 2-4, FIG. 6C shows measurements of single Au thin films of Comparative Examples 4-1 to 4-3, FIG. 6D shows measurements of single Ag thin films of Comparative Examples 5-1 to 5-3, and FIG. 6E shows measurements of single TiOx thin films of Comparative Examples 3-1 to 3-3.

FIGS. 6A through 6E show that the average SE increases linearly with the thickness of the shielding films, and FIG. 6F shows that the single copper thin film has superior shielding efficiency compared to the single MXene thin film. However, the average SE of the Comparative Examples shown in FIG. 6 did not exceed 50 dB.

On the other hand, FIGS. 7A through 7J show graphs illustrating the measured SE values of the electromagnetic interference shielding films of Preparation Examples 1-1 to 1-3, where FIGS. 7A, 7D, and 7G relate to Preparation Example 1-1, FIGS. 7B, 7E, and 7H relate to Preparation Example 1-2, and FIGS. 7C, 7F, and 7I relate to

### Preparation Example 1-3.

Referring to FIGS. 7A through 7J, the electromagnetic interference shielding films have excellent average SE values of 50 dB or higher compared to the single metal thin films of the Comparative Examples shown in FIGS. 6A through 6F, and as shown in FIG. 7F, the electromagnetic interference shielding film also has superior average SE values compared to the Comparative Examples.

Therefore, referring to FIGS. 6A through 6F and FIGS. 7A through 7J, it can be seen that, compared to the single copper thin film and the single MXene thin film, when the copper thin film and the MXene thin film form a sandwich structure, the copper and MXene are selectively improved, which increases the SE_{A} and thereby enhances the SEₜₒₜₐₗ.

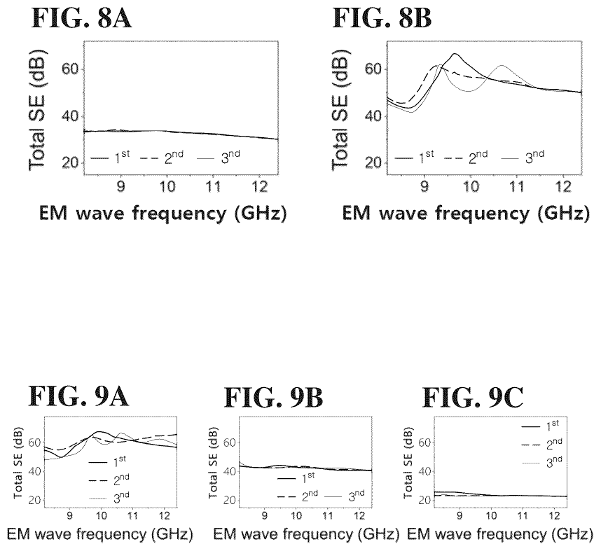

FIGS. 8A and 8B show graphs illustrating the repeatedly measured SEₜₒₜₐₗ values of the electromagnetic interference shielding films of FIG. 8A Preparation Example 1-3 and FIG. 8B Comparative Example 6.

FIGS. 9A through 9C show graphs illustrating the repeatedly measured SEₜₒₜₐₗ values of the electromagnetic interference shielding films of FIG. 9A Preparation Example 1-4, FIG. 9B Comparative Example 1-4, and FIG. 9C Comparative Example 2-3.

Referring to FIGS. 8A through 8B and FIGS. 9A through 9C, the electromagnetic interference shielding film having a thickness of 0.4 μm prepared in Preparation Example 1-3, in which a 0.2 μm thick MXene layer was formed between copper thin films, had a superior SEₜₒₜₐₗ value compared to Comparative Example 6, in which an Al₂O₃ layer having the same thickness was formed, as shown in FIGS. 8A and 8B. As shown in FIGS. 9A through 9C, the electromagnetic interference shielding films having a thickness of 0.6 μm prepared in Preparation Example 1-4, Comparative Example 1-4, and Comparative Example 2-3 show that the single metal thin films of Comparative Example 1-4 and Comparative Example 2-3 have significantly lower SEₜₒₜₐₗ values than Preparation Example 1-4.

Therefore, referring to FIGS. 8A and 8B and FIGS. 9A through 9C, it can be seen that the electromagnetic interference shielding film having the sandwich structure of Preparation Example 1-4 exhibits superior shielding performance compared to the single metal thin film, and that even when the same sandwich structure is used, the combination of the metal thin film and the MXene layer results in superior shielding efficiency. In addition, when comparing the graphs of Preparation Example 1-3 and Preparation Example 1-4, the thickness of the MXene layer did not produce a significant difference in the electromagnetic shielding effect.

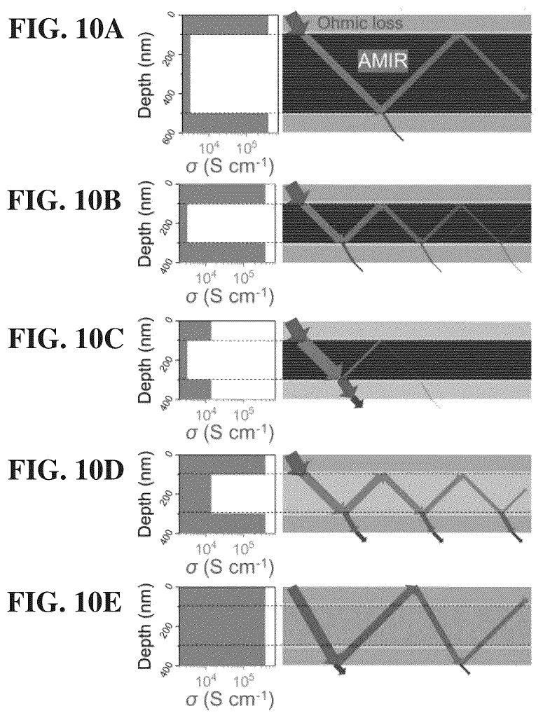

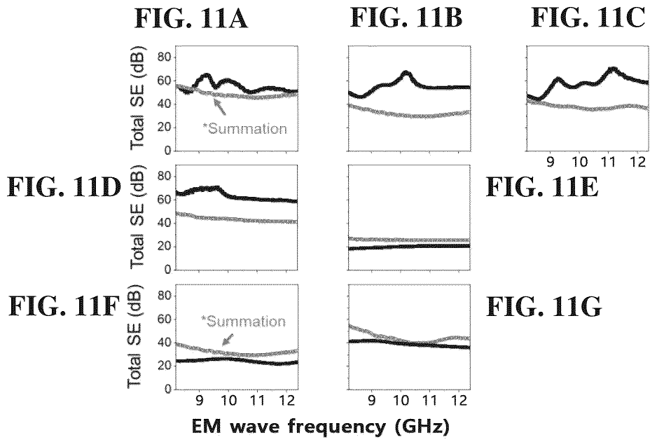

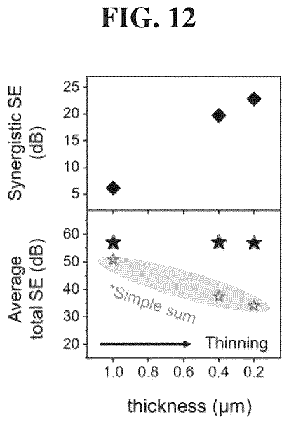

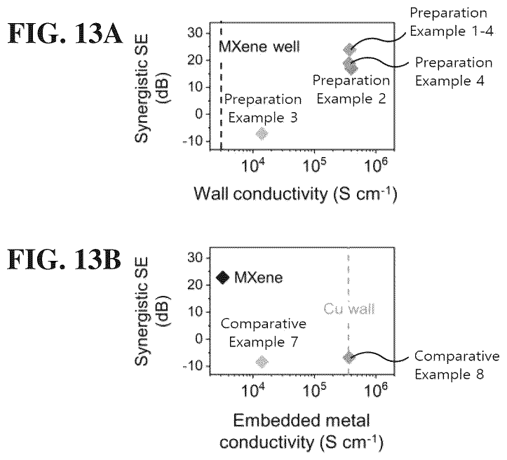

FIGS. 10A through 10E show graphs illustrating the AMIR mechanism of FIG. 10A Preparation Example 1-3, FIG. 10B Preparation Example 1-4, FIG. 10C Preparation Example 3-2, FIG. 10D Comparative Example 7, and FIG. 10E Comparative Example 8. FIGS. 11A through 11G show graphs illustrating the SEₜₒₜₐₗ values of FIG. 11A Preparation Example 1-5, FIG. 11B Preparation Example 1-4, FIG. 11C Preparation Example 4-2, FIG. 11D Preparation Example 2-2, FIG. 11E Preparation Example 3-2, FIG. 11F Comparative Example 7, and FIG. 11G Comparative Example 8. FIG. 12 shows graphs illustrating the synergistic SE and the average SE of Preparation Examples 1-3 to 1-5, and FIGS. 13A and 13B show graphs illustrating the measured synergistic SE values of the Preparation Examples and Comparative Examples 7 and 8.

Referring to FIGS. 10A through 10E, FIGS. 10A to 10D form a well-shaped structure. FIGS. 10A and 10B show that the copper thin film functions as a wall that confines electromagnetic waves, allowing effective AMIR to occur within the MXene layer, which is electrically conductive and rich in dipoles, when the electromagnetic waves are absorbed. However, when comparing FIGS. 10A and 10B, the difference in the thickness of a single MXene layer did not significantly affect AMIR. However, since FIGS. 10A and 10B can perform a superior AMIR mechanism compared to FIGS. 10C and 10D, it can be inferred that effective AMIR occurs through the heterogeneous junction between the metal thin film and the MXene layer. Referring to FIGS. 11A through 11G to more specifically verify this mechanism, in FIGS. 11C and 11D, where the metal thin film is Au or Ag, similar SEₜₒₜₐₗ values were observed compared to FIG. 11B, which is an electromagnetic interference shielding film of the same thickness using a copper thin film, because Au and Ag have superior electrical conductivity. However, in FIG. 11E, AMIR did not operate smoothly due to the resistive properties of TiOx. Moreover, in FIG. 11F, instead of the MXene layer, TiOx, which has electrical conductivity similar to that of MXene, was deposited between the copper thin films, but the AMIR mechanism did not occur. In FIG. 11G, the AMIR mechanism also did not occur because the conductivities of Cu and Au are similar, and thus the synergistic SE was not measured in FIGS. 13A and 13B.

Therefore, referring to FIGS. 10A and 13B, it can be seen that the conductivity mismatch at the junction between the metal thin film and the MXene layer allows electromagnetic waves to be efficiently confined within the MXene layer, and that the electromagnetic interference shielding film comprising the copper thin film and the MXene layer exhibits the highest shielding efficiency.

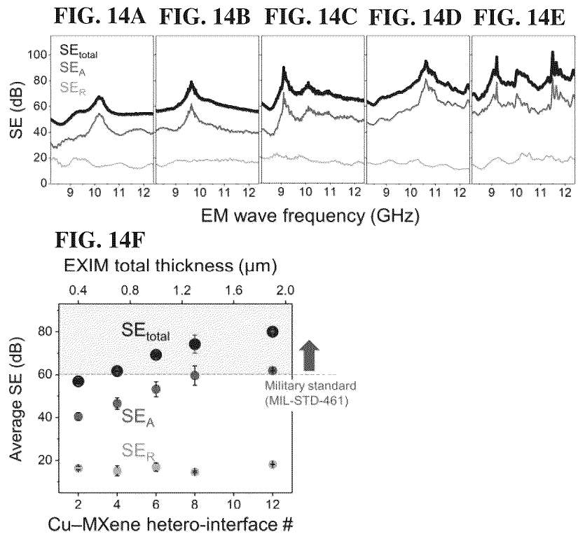

FIGS. 14A through 14F show graphs illustrating the SE measurement results of the multilayer structures of Preparation Examples 1-4 and 1-6 to 1-9. FIG. 14A relates to Preparation Example 1-4, FIG. 14B relates to Preparation Example 1-6, FIG. 14C relates to Preparation Example 1-7, FIG. 14D relates to Preparation Example 1-8, and FIG. 14E relates to Preparation Example 1-9.

Referring to FIGS. 14A through 14F, it can be seen that the SE value increases as the number of junctions between the copper thin film and the MXene layer increases. Therefore, it can be understood that the electromagnetic interference shielding film comprising a heterogeneously stacked metal-MXene improves the SE by the occurrence of AMIR at the junctions between the copper thin film and the MXene layer due to the conductivity mismatch between them, rather than by the thickness of the MXene layer.

### Measurement Example 3

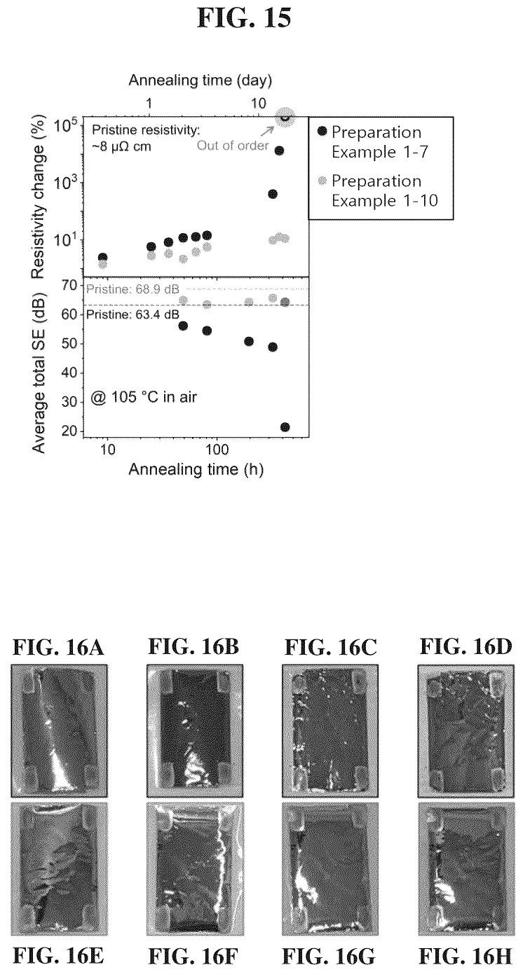

FIG. 15 shows graphs illustrating the measured average SE and electrical resistance values of the electromagnetic interference shielding films depending on the presence or absence of a passivation layer in Preparation Examples 1-7 and 1-10.

Referring to FIG. 15, the copper thin film and the MXene layer are vulnerable to oxidation, which may affect the shielding stability. Therefore, it is more preferable to form a passivation layer on the uppermost metal thin film of the electromagnetic interference shielding film comprising a heterogeneously stacked metal-MXene. The passivation layer may have a reduced thickness of 20 μm or less, which maintains the bending rigidity of the electromagnetic interference shielding film while preventing the deterioration of shielding performance caused by humidity, discoloration, and mechanical cracking.

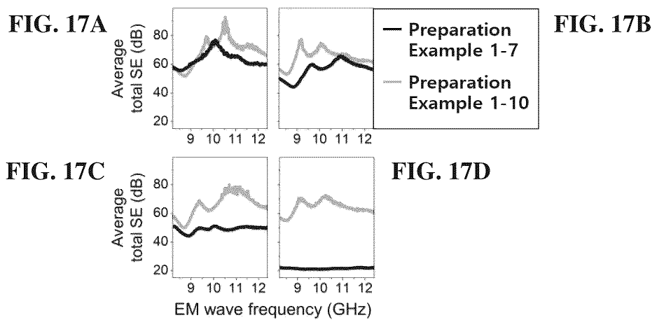

FIGS. 16A through 16H show images illustrating the changes in the surface morphology of the electromagnetic interference shielding films over time depending on the presence or absence of a passivation layer, where FIGS. 16A to 16D relate to Preparation Example 1-7 without the passivation layer and FIGS. 16E to 16H relate to Preparation Example 1-10 with the passivation layer. FIGS. 17A through 17D show graphs illustrating the corresponding average SE curves. In FIGS. 16A through 16H and 17A through 17D, the observations were made at pristine, 49 hours, 324 hours, and 420 hours. In Preparation Example 1-10, the electromagnetic interference shielding film exhibited almost no discoloration compared to the initial state, and the average SEₜₒₜₐₗ value did not decrease.

Therefore, referring to FIGS. 16A through 16H and 17A through 17D, it can be seen that the presence of the passivation layer can maintain the shielding performance.

### Measurement Example 4

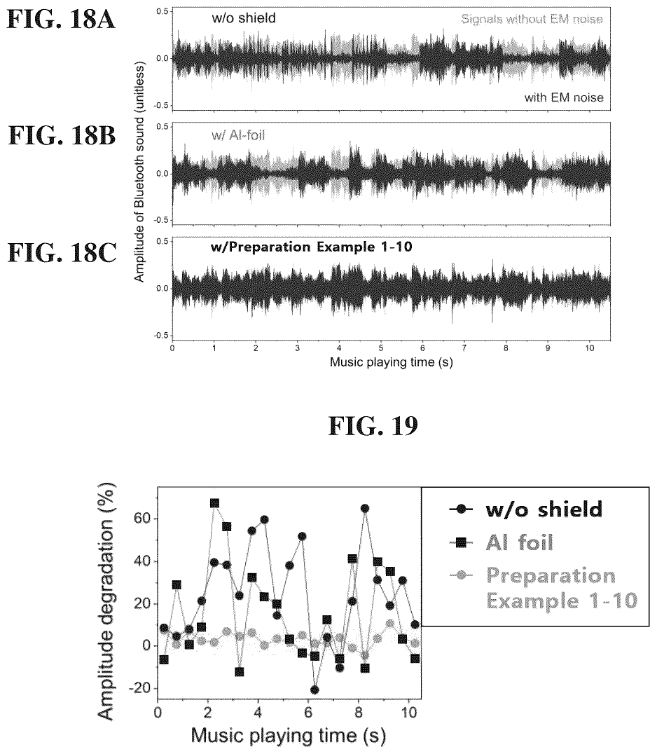

FIGS. 18A through 18C show graphs illustrating the malfunctions caused by electromagnetic noise from a Bluetooth speaker. Under conditions that interfere with communication between a Bluetooth dongle of a mobile phone and a speaker by an IC chip of a USB 3.0 drive that generates EM noise, the sound amplitude integrity was examined when the speaker was covered with aluminum foil and when the shielding film of preparation Example 1-10 was applied.

FIG. 19 is a graph illustrating the effect of shielding on the integrity of the Bluetooth signal shown in FIGS. 18A through 18C.

Referring to FIGS. 18A through 18C and 19, compared to FIGS. 18A and 18B, FIG. 18C effectively mitigates electromagnetic waves and reduces noise, as can be seen from FIG. 19.

Therefore, according to the present inventive concept as described above, the electromagnetic interference shielding film comprising a heterogeneously stacked metal-MXene can be prepared to have a reduced thickness compared to conventional electromagnetic interference shielding films including pores, since the non-porous MXene layer is inserted into the metal thin film layers and is therefore not restricted by the minimum thickness required for forming pores, and the resulting film exhibits excellent uniformity and processing compatibility. Therefore, the electromagnetic interference shielding film comprising a heterogeneously stacked metal-MXene has low bending rigidity due to its reduced thickness and thus can be easily formed on the surfaces of various IC chips. Moreover, since it does not require a step of additionally forming a pore structure within the electromagnetic interference shielding film comprising a heterogeneously stacked metal-MXene, it exhibits excellent spatial uniformity and reproducibility, and therefore the passivation yield does not decrease, resulting in excellent shielding performance.

The electromagnetic interference shielding film comprising a heterogeneously stacked metal-MXene forms an electromagnetic wave confinement barrier due to a high reflection loss at the interface where the metal thin film layer and the MXene layer are joined, which results from the conductivity mismatch between the metal thin film layer and the MXene layer. Furthermore, the interface and the dipoles of MXene flakes absorb reflected waves and thereby generate effective absorption during multiple internal reflections (AMIR) within the electromagnetic interference shielding film, thus achieving excellent electromagnetic shielding efficiency.

The electromagnetic interference shielding film comprising a heterogeneously stacked metal-MXene can have a multilayer stacked structure in which a metal thin film layer and an MXene layer are stacked in sequence, and can have excellent shielding performance as the joint portion of the metal thin film layer and the MXene layer increases.

While the inventive concept has been shown and described with reference to certain preferred embodiments thereof, it will be understood by those skilled in the art that various changes in form and details may be made therein without departing from the spirit and scope of the inventive concept as defined by the appended claims. Therefore, the scope of the inventive concept is defined not by the detailed description of the inventive concept but by the appended claims, and all differences within the scope will be construed as being included in the present inventive concept.

What is claimed is:

1. An electromagnetic interference shielding film comprising a heterogeneously stacked metal-MXene in a sandwich structure, the electromagnetic interference shielding film comprising:
a lower metal thin film;
an MXene layer positioned on the metal thin film; and
an upper metal thin film for electromagnetic shielding positioned on the MXene layer and made of the same material as the lower metal thin film,
wherein the lower metal thin film and the upper metal thin film induce absorption during multiple internal reflections (AMIR) by dipoles on the surface of the MXene layer at interfaces in contact with the MXene layer.

2. The electromagnetic interference shielding film comprising a heterogeneously stacked metal-MXene according to claim 1, wherein the electromagnetic interference shielding film has a multilayer structure including two or more MXene layers formed by repeatedly stacking the metal thin films and the MXene layers.

3. The electromagnetic interference shielding film comprising a heterogeneously stacked metal-MXene according to claim 2, wherein the electromagnetic interference shielding film has a thickness of 0.4 μm to 2 μm.

4. The electromagnetic interference shielding film comprising a heterogeneously stacked metal-MXene according to claim 3, wherein the MXene layer has a thickness of 0.2 μm or less.

5. The electromagnetic interference shielding film comprising a heterogeneously stacked metal-MXene according to claim 4, wherein the electromagnetic interference shielding film has an electromagnetic shielding effectiveness (SE) of 69.2 (±1.6 ) dB or higher.

6. The electromagnetic interference shielding film comprising a heterogeneously stacked metal-MXene according to claim 1, wherein the metal thin film is any one selected from the group consisting of metal materials including Cu, Au, and Ag.

7. A method for preparing an electromagnetic interference shielding film comprising a heterogeneously stacked metal-MXene, the method comprising:
forming a sacrificial layer on a substrate;
depositing a lower metal thin film on the sacrificial layer;
coating an interfacial adhesion promoter on the lower metal thin film;
coating an MXene layer on the lower metal thin film coated with the interfacial adhesion promoter;
coating an interfacial adhesion promoter on the MXene layer; and
depositing an upper metal thin film on the MXene layer coated with the interfacial adhesion promoter.

8. The method for preparing an electromagnetic interference shielding film comprising a heterogeneously stacked metal-MXene according to claim 7, wherein the electromagnetic interference shielding film has a multilayer structure including two or more MXene layers formed by repeatedly stacking the metal thin films and the MXene layers.

9. The method for preparing an electromagnetic interference shielding film comprising a heterogeneously stacked metal-MXene according to claim 7, wherein the electromagnetic interference shielding film further comprises a passivation layer formed on the upper metal thin film.

10. The method for preparing an electromagnetic interference shielding film comprising a heterogeneously stacked metal-MXene according to claim 7, wherein the electromagnetic interference shielding film has a thickness of 2 μm or less.

11. The method for preparing an electromagnetic interference shielding film comprising a heterogeneously stacked metal-MXene according to claim 7, wherein the MXene layer has a thickness of 2 μm or less.

12. The method for preparing an electromagnetic interference shielding film comprising a heterogeneously stacked metal-MXene according to claim 7, wherein the electromagnetic interference shielding film has an electromagnetic shielding effectiveness (SE) of 69.2 (±1.6 ) dB or higher.

13. The method for preparing an electromagnetic interference shielding film comprising a heterogeneously stacked metal-MXene according to claim 7, wherein the metal thin film is any one selected from the group consisting of metal materials including Cu, Au, Ag, and TiOx.
